(19) United States
(12) Patent Application Publication
(10) Pub. No.: US 2025/0357068 A1
(43) Pub. Date: Nov. 20, 2025

(54) ELECTRON BEAM INSPECTIONS WITH HIGH SENSITIVITY AND THROUGHPUT

(71) Applicant: KLA CORPORATION, Milpitas, CA (US)

(72) Inventors: Xinrong JIANG, Palo Alto, CA (US); Ralph NYFFENEGGER, Palo Alto, CA (US); Harsh SINHA, Santa Clara, CA (US)

(21) Appl. No.: 19/198,108

(22) Filed: May 4, 2025

Related U.S. Application Data
(60) Provisional application No. 63/647,078, filed on May 14, 2024.

(51) Int. Cl. H01J 37/073; H01J 37/14; H01J 37/147; H01J 37/153; H01J 37/244

(52) U.S. Cl. CPC H01J 37/073; H01J 37/14; H01J 37/1474; H01J 37/153; H01J 37/244; H01J 2237/1534; H01J 2237/24475; H01J 2237/2448

(57) ABSTRACT

A system can define at least one care area on the workpiece for defects detected on a surface or underneath a surface of the workpiece using data from an optical inspector. The system also can define at least one care area for the workpiece that includes defects buried in the workpiece. The system can generate an electron beam using a cold field emission electron source, such as to inspect a high aspect ratio structure.

### CROSS-REFERENCE TO RELATED APPLICATIONS

This application claims priority to the provisional patent application filed May 14, 2024 and assigned U.S. App. No. 63/647,078, the disclosure of which is hereby incorporated by reference.

### FIELD OF THE DISCLOSURE

This disclosure relates to workpiece inspection using an electron beam.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a workpiece like a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Today's leading-edge integrated circuits (ICs) are fabricated using intricate shapes and new materials with structures that are smaller, narrower, taller, and deeper. Inspection methods are used at various steps during a semiconductor manufacturing process to detect defects on wafers or other workpieces to promote higher yields in the manufacturing process. As the dimensions of semiconductor devices decrease, inspection becomes even more important to the successful manufacture of acceptable semiconductor devices because smaller defects may cause the devices to fail.

As design rules shrink, however, semiconductor manufacturing processes may be operating closer to the limitation on the performance capability of the processes. In addition, smaller defects can have an impact on the electrical parameters of the device as the design rules shrink, which drives more sensitive inspections. As design rules shrink, the population of potentially yield-relevant defects detected by inspection grows dramatically, and the population of nuisance defects detected by inspection also increases dramatically. Therefore, more defects may be detected on the wafers, and correcting the processes to eliminate all of the defects may be difficult and expensive. Determining which of the defects actually have an effect on the electrical parameters of the devices and the yield may allow process control methods to be focused on those defects while largely ignoring others. Furthermore, at smaller design rules, process-induced failures, in some cases, tend to be systematic. That is, process-induced failures tend to fail at predetermined design patterns often repeated many times within the design. Elimination of spatially-systematic, electrically-relevant defects can have an impact on yield.

Semiconductor devices fabricated on semiconductor wafers or other workpieces can be inspected using a scanning electron beam inspection tool, such as a scanning electron microscope (SEM). The low throughput on this kind of inspection tool tends to be an obstacle because the images are acquired pixel-by-pixel over a field of view (FOV) in a sequential manner as shown in FIG. 1. FIG. 1 illustrates a “full-region” defect detection technique. The “full-region” is an IC die, and a die is divided into many FOVs. An electron beam is scanned over the FOV, and secondary electron signals are collected for detecting defects. An FOV may be limited to around ten of microns due to deflection aberrations of scanning system. The stage holding the wafer or other workpiece moves the next FOV into the previous FOV position after the previous FOV is finished scanning. An increase in the number of stage motions lowers the throughput. A low throughput with a direct FOV-scanning raises inspection costs.

A defect of interest (DOI) also may be first defined by optical inspectors with higher throughputs. When semiconductor fabrication facilities (fabs) use optical inspector tools to monitor defects on the workpiece, the inspection recipe on the optical inspector tool is optimized for DOIs. The DOI regions may then be either inspected or reviewed by an electron beam scanning over an FOV (like the FOV in FIG. 1) for the defect detection and classification with higher resolution (sensitivity) than the optical inspector. However, defects are detected by subtracting a reference from an image of the defect sites to locate the defect. Such a technique deals with subtracting the whole images within certain FOVs with the defect image. Besides requiring large computation power for pixel-by-pixel analysis, it increases the probability of including a nuisance or instances of multiple, non-important defects. There may be higher throughput costs for detection because complete SEM images with FOV are processed for detection even if part of FOV is not an area of interest. Furthermore, if an electron beam detection and classification is used for the defects coming from an optical inspector, a nuisance on the workpiece could have an adverse impact. For example, a DOI might get reported into a nuisance bin, or a nuisance might be also reported in a defect bin. It can be difficult to implement a region-specific (e.g., care area or hot spot) defect selectivity.

Improved systems and techniques are needed.

### BRIEF SUMMARY OF THE DISCLOSURE

A system is provided in a first embodiment. The system includes a cold field emission electron source that generates an electron beam; a stage configured to hold a workpiece in a path of the electron beam; a magnetic lens disposed along the path of the electron beam between the cold field emission source and the stage; a Wien filter disposed along the path of the electron beam between the magnetic lens and the stage; a detector configured to collect secondary electrons; an annular detector configured to collect back scattered electrons; and a scanning system disposed along the path of the electron beam between the magnetic lens and the Wien filter. The scanning system includes at least one deflector.

The cold field emission source may have an emitter tip with a radius configured to provide an electron emission of at least 1.4×10⁹ A/(m²·sr·V).

The system can include a processor in electronic communication with the system and an optical inspector in electronic communication with the processor. In an instance, the processor is configured to define at least one care area on the workpiece for defects detected on a surface or underneath a surface of the workpiece using data from the optical inspector; and define at least one care area for the workpiece that includes defects buried in the workpiece.

The system can include a defect location accuracy system operated by the processor, wherein the defect location accuracy system is configured to determine how accurately the coordinate systems of the system and the optical inspector are matched.

A method is provided in a second embodiment. The method includes generating an electron beam with a cold field emission electron source. The electron beam is directed to a workpiece on a stage through a magnetic lens, a scanning system downstream of the magnetic lens, and a Wien filter downstream of the scanning system. Secondary electrons from the workpiece are detected with a side detector. Back scattered electrons are detected with an annular detector.

The cold field emission source may have an emitter tip with a radius and voltage configured to provide an electron emission of at least 1.4×10⁹ A/(m²·sr·V).

The electron emission may have a source energy spread from 0.4 to 0.5 eV. A Boersch effect may be reduced to less than 0.5 eV.

The magnetic lens may have a working distance between an objective lens and the workpiece of 1 to 3 mm.

The side detector may be configured to provide data for detecting defects on a surface of the workpiece.

The annular detector may be configured to provide data for detecting defects buried in the workpiece.

The scanning system may provide an energy spread from 0.4 to 0.5 eV thereby reducing transverse chromatic aberrations.

The method may include defining at least one care area on the workpiece for defects detected on a surface or underneath a surface of the workpiece using a processor. The at least one care area on the workpiece for defects detected on a surface or underneath a surface of the workpiece are defined using data from an optical inspector. In an instance, the method includes defining at least one care area for the workpiece that includes defects buried in the workpiece using the processor.

The resolution of the electron beam may be 1 nm or less.

A high aspect ratio structure on the workpiece may be inspected using the electron beam.

### DESCRIPTION OF THE DRAWINGS

For a fuller understanding of the nature and objects of the disclosure, reference should be made to the following detailed description taken in conjunction with the accompanying drawings, in which:

FIG. 1 is a previous technique for detecting defects during workpiece inspection;

FIG. 2 is an embodiment of a system for electron beam inspection in accordance with the present disclosure;

FIG. 3 is a chart showing percentage of CFE-optics spot size to TFE-optics spot size in low beam current uses of metrologies (e.g., BC≤1.0 nA);

FIG. 4 is a chart showing percentage of CFE-optics spot size to TFE-optics spot size in high beam current uses of inspections (e.g., 1.0<BC<30 nA);

FIG. 5 is an exemplary CFE gun with high brightness in accordance with the present disclosure;

FIG. 6 is an exemplary simulation of electron emissions and trajectories in a high brightness CFE gun;

FIG. 7 shows exemplary CFE emitting electrons (trajectories) near an emitter tip for electrons limited by the beam limiting aperture;

FIG. 8 is a schematic of a defect detection at the bottom of a memory hole in a 3D NAND;

FIG. 9 is a computer simulation of a high landing energy beam spot size at the top surface of a high aspect ratio memory hole; and

FIG. 10 is a computer simulation of a high landing energy beam spot size at the bottom of a high aspect ratio memory hole.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

An improved technique of electron beam defect detection is disclosed in the embodiments herein. This is referred to as care area defect detection. The care area inspection with a high-resolution electron beam captures and identifies defects with higher sensitivity and throughput. With an electron optics design integrated together with a high brightness cold field emission (CFE) gun, the electron beam inspection technique disclosed herein can identify the defects of workpieces down to one nanometer. Care area inspection and care area defect detection improve the efficiency of defect detection algorithms by reducing the amount of image processing needed and increases the probability of filtering important DOIs. A care area can be defined by a separate optical inspector or by a user based on an IC design file. Wider landing energies (e.g., from 0.1 to 50 keV) and highest resolution down to one nanometer can be used to capture physical and high aspect ratio (HAR) defects, supporting process development and production monitoring for advanced logic, DRAM, and 3D NAND devices.

Embodiments disclosed herein can enable defect inspection of intricate shapes and new materials, including structures that are smaller, narrower, taller, or deeper. The care area workpiece inspection with a high-resolution electron beam captures and identifies defects with higher sensitivity and throughput. Compared to the conventional electron beam FOV scanning detection around tens of microns, an electron beam care area (e.g., sub-micron) scanning detection can remove nuisance issues. The DOI and nuisances can be present within a FOV of SEM images used for detection. If the nuisance is more obvious on the SEM images, even though it is of no interest to the users, SEM detection may lead to detection of nuisance. Since the defect classification relies on defect detection, it can lead to incorrect classification of the defect. Smaller care areas for inspection can overcome this problem.

The care area may be defined by an IC design file for the detection of defects buried at the bottom of 3D devices. The electron optics design disclosed herein used with a high brightness CFE gun makes it possible to detect the defects for 3D devices (e.g., 3D NAND) with an aspect ratio (AR) up to 1:100. In an example, an electron beam with large depth of focus (DOF) can scan across a 50 nm-width and 5000 nm-depth memory hole while delivering a beam current of 10 nA for a high yield of BSEs.

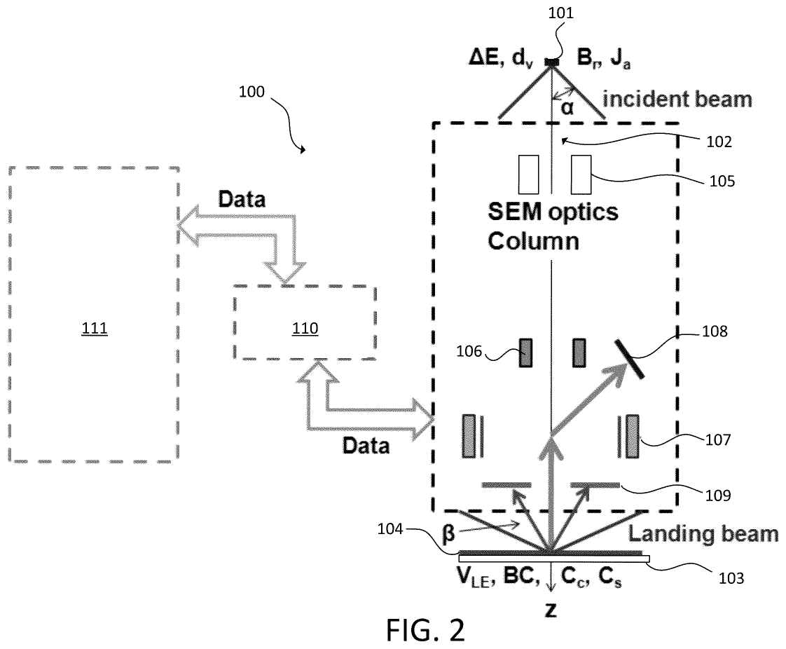

FIG. 2 is an embodiment of a system 100 for electron beam inspection. The system includes a virtual source, which may be a cold field emission electron source 101 that generates an electron beam 102. The cold field emission source 101may have an emitter tip with a radius configured to provide an electron emission (brightness) of at least 1.4×10⁹ A/(m²·sr·V). The virtual source can be characterized by a source energy spread (ΔE), a virtual source size (dv), a reduced virtual source brightness (Br), a virtual source angular intensity (Ja), and an electron emission angle (α). A description of image-forming resolution on wafer characterized by a landing energy (LE) voltage (VLE), a beam current (BC), a spherical aberration coefficient (Cs), a chromatic aberration coefficient (Cc), and a numeric aperture angle (β). A stage 103 is configured to hold a workpiece 104 (e.g., a semiconductor wafer) in a path of the electron beam 102.

A magnetic lens 105 is disposed along the path of the electron beam 102 between the cold field emission source 101 and the stage 103.

A scanning system 106 is disposed along the path of the electron beam between the magnetic lens 105 and a Wien filter 107. The scanning system 106 includes at least one deflector. A dual-deflector system coupled with the Wien filter 107 may provide minimum deflection aberrations with a telecentric electron beam landing angle.

A Wien filter 107 is disposed along the path of the electron beam between the magnetic lens 105 and the stage 103. In an instance, the Wien filter 107 is between the scanning system 106 and the stage 103. A detector 108 is configured to collect secondary electrons. This can be positioned off-axis relative to the path of the electron beam 102. The detector 108 and Wien filter 107 can be used as a secondary electron (SE) collection system, which can be used for detecting the defects on the surface of the workpiece 104.

An annular detector 109 is configured to collect back scattered electrons. The annular detector 109 can be used for collecting BSE signals from deep layers of workpiece 104.

Components of the system 100 are in electronic communication with a processor 110. The processor 110 can receive data from the detector 108, the annular detector 109, or other parts of the system 100. The processor 110 also can receive data from the broad band plasma (BBP) optical inspector 111. The processor 110 typically comprises a programmable processor, which is programmed in software and/or firmware to carry out the functions that are described herein, along with suitable digital and/or analog interfaces for connection to the other elements of the system 100. Alternatively or additionally, the processor 110 comprises hard-wired and/or programmable hardware logic circuits, which carry out at least some of the functions of the processor 110. Although the processor 110 is shown in FIG. 2, for the sake of simplicity, as a single, monolithic functional block, in practice the processor 110 may comprise multiple, interconnected control units, with suitable interfaces for receiving and outputting the signals that are illustrated in the figures and are described in the text. Program code or instructions for the processor 110 to implement various methods and functions disclosed herein may be stored in readable storage media, such as a memory or other memory. The processor 110 can send instructions to the system 100 to execute embodiments of the operation disclosed herein.

In an instance, the processor 110 can be configured to define at least one care area on the workpiece 104 for defects detected on a surface or underneath a surface of the workpiece 104 using data from an optical inspector 111. The processor 110 also can be configured to define at least one care area for the workpiece 104 that includes defects buried in the workpiece 104. Design data for the workpiece 104 can be used to help define the care area.

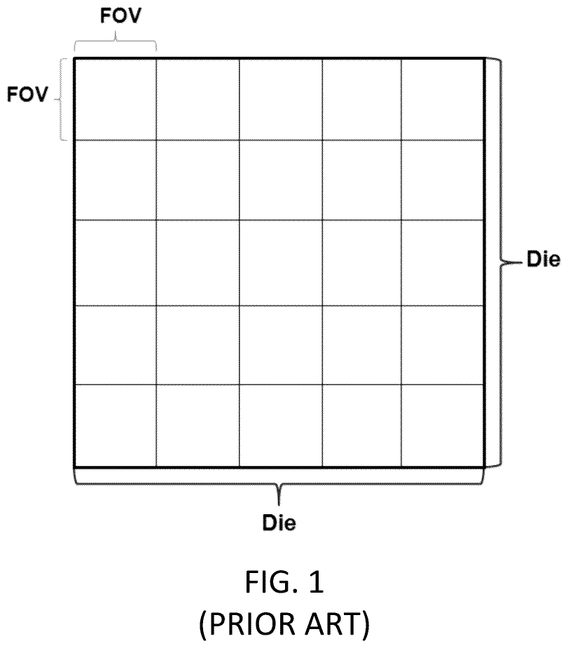

Care areas with defects can be provided by the BBP optical inspector 111, which enables discovery of yield-critical defects around nanometer-order logic and leading-edge memory design nodes. A BBP optical inspector 111 may capture critical defects across a range of process layers, material types, and process stacks. The care area may be smaller than an FOV in FIG. 1. For instance, a care area may be a polygon-shaped zone with a size from approximately 0.2 μm by 0.2 μm to approximately 0.5 μm by 0.5 μm. In an instance, the BBP optical inspector 111 uses a 190-266 nm wavelength range to provide high sensitivity for critical defect types at a high throughput for reticle re-qualification in high volume manufacturing (HVM) phase. The BBP optical inspector 111 may be directly integrated into the system 100 or can communicate with the system 100, as shown in FIG. 2.

While disclosed with the BBP optical inspector 111, other optical inspectors may be used. A laser scanning inspection system can support defect monitoring for advanced logic and memory chip manufacturing. For example, a deep learning algorithm can separate key DOIs from pattern nuisance defects to improve the overall defect capture rate of the defects that matter, including unique, subtle defects.

Optical inspectors may be limited to detect the defects on the surface of a workpiece. It also may be difficult to determine where the defect is located using an optical inspector, which is why a two-pass strategy using two wavelengths may be used. For example, a wavelength of approximately 266 nm can be used to find surface defects. Higher wavelengths can penetrate the workpiece to find bulk defects. Bulk defects can be determined by subtracting the two results generated with the different wavelengths.

The care areas on the workpiece 104 can be inspected with the electron beam 102. The throughput of the electron beam 102 inspection is improved because the defects are in small care areas. The resolution of the SEM image-formation can be improved for high sensitivity of defect detections. In an instance, image-forming resolutions down to one nanometer may be performed.

The defect location accuracy (DLA) system can determine how accurately the coordinate systems of system 100 and the BBP optical inspector 111 can be matched so that defects reported by one tool can be visited by the other tool. The DLA can be run using the processor 110. For example, the DLA can determine the accuracy with which a defect reported by the BBP optical inspector 111 can be located by the system 100. With the trend of IC critical dimension shrinkages, an improved DLA between BBP inspector 111 and the system 100 can enable better detection of defects.

During operation, the electron beam 102 is generated using the cold field emission electron source 101 to the workpiece 104 on the stage 103. The electron beam 102 is directed through the magnetic lens 105, the scanning system 106 downstream of the magnetic lens 105, and the Wien filter 107 downstream of the scanning system 106. Secondary electrons are detected with the side detector 108, which can provide data for detecting defects on a surface of the workpiece. Back scattered electrons are detected with the annular detector 109, which can provide data for detecting defects buried in the workpiece 104. The CFE electron emission can have a source energy spread from approximately 0.4 to 0.5 eV. A Boersch effect can be reduced to less than 0.5 eV. The magnetic lens can have a working distance between an objective lens and the workpiece from approximately 1 to 3 mm adjustable, depending on landing energy. The scanning system can provide an energy spread from approximately 0.4 to 0.45 eV with a CFE source thereby reducing transverse chromatic aberrations. Resolution of the electron beam 102 may be 1 nm or less.

In an instance, at least one care area on the workpiece 104 for defects detected on a surface or underneath a surface of the workpiece 104 can be defined using the processor 110. The at least one care area on the workpiece 104 is defined using data from an optical inspector, such as the BBP optical inspector 111. At least one care area for the workpiece 104 that includes defects buried in the workpiece 104 also can be defined using the processor 110.

High resolution image-formation can be provided using the embodiments disclosed herein. Without including the influence of Coulomb interactions between electrons, the total spot size (SS) of a landing electron beam on the workpiece 104 in FIG. 2 include the source image d_{g}, the spherical aberration blur dₛ, the chromatic aberration blur dₑ, and the diffraction aberration blur d_{λ}. These relationships are shown in the following Equations (1)-(5).

$${d}_{g} = 0.707 {( \frac{BC}{{π}^{2} {β}^{2} {V}_{LE} {B}_{r} / 4} )}^{1 / 2} \qquad ( 1 )$$

$${d}_{s} = 0.18 {C}_{s} {β}^{3} \qquad ( 2 )$$

$${d}_{c} = 0.34 {C}_{c} \frac{Δ E}{{V}_{LE}} β \qquad ( 3 )$$

$${d}_{λ} = 0.54 \frac{λ}{β} , λ = \frac{h}{\sqrt{2 {meV}_{LE}}} \qquad ( 4 )$$

$$SS = {( {d}_{g}^{2} + {d}_{s}^{2} + {d}_{c}^{2} + {d}_{λ}^{2} )}^{1 / 2} \qquad ( 5 )$$

In Equation (4), λ is the electron wavelength, m is the electron mass, e is the electron charge and h is the Planck constant. Bᵣ in Equation (1) is referred to as a reduced source brightness, given by Equation (6) in which Jₐ is the virtual source angular intensity.

$${B}_{r} = \frac{4 {J}_{α}}{π {d}_{v}^{2} {V}_{ext}} \qquad ( 6 )$$

For the system 100 in FIG. 2, the gun lens is designed as a magnetic lens. The electron optics can be divided into two applications: a low beam current (BC) case (e.g., BC≤1.0 nA) for electron beam metrologies and a high beam current case (e.g., 1.0<BC<30.0 nA) for electron beam inspections across care areas. In a low beam current case, Equation (5) can be simplified as Equation (7).

$$SS \approx {( {d}_{λ}^{2} + {d}_{c}^{2} )}^{\frac{1}{2}} \qquad ( 7 )$$

Equation (7) shows that the diffraction aberration blur (d_{λ}) and chromatic aberration blur (d_{c}) are dominant in the electron beam column optics. Substituting Equation (3) and Equation (4) into Equation (7) provides an optimal numeric aperture angle (βₒₚₜ) given by Equation (8).

$${β}_{opt}^{2} = {k}_{1} \frac{{V}_{LE}^{1 / 2}}{{C}_{c} Δ E} \qquad ( 8 )$$

The minimum spot size at βₒₚₜ given by Equation (9).

$$SS = {{ρ}_{1} ( \frac{{C}_{c} Δ E}{{V}_{LE}^{3 / 2}} )}^{1 / 2} \qquad ( 9 )$$

In Equation (8) and Equation (9), k₁ and p₁ are constants. The C_{c} in Equation (9) should be a total chromatic aberration coefficient, given by Equation (10) where C_{cOL} and C_{cGUN} are the chromatic aberration coefficients of the objective lens and gun lens, respectively.

$${C}_{c} = {C}_{cOL} + {M}^{2} * {C}_{cGUN} * {( \frac{{V}_{LE}}{{V}_{ext}} )}^{3 / 2} \qquad ( 10 )$$

The M in Equation (10) is the optical magnification, given by Equation (11).

$$M = \frac{1}{{β}_{opt}} * \sqrt{\frac{BC}{π {J}_{a}}} * \sqrt{\frac{{V}_{ext}}{{V}_{LE}}} \qquad ( 11 )$$

From Equation (9), in the low beam current regions (BC≤1.0 nA) for electron beam metrologies, the spot size (SS) is independent of source brightness Bᵣ and the image-formation resolution is limited by the source energy spread ΔE. The C_{c} and V_{LE} are use conditions. For a magnetic gun, the gun lens chromatic aberration coefficient (C_{cGUN}) is smaller than an electrostatic gun, so the second term in Equation (10) is normally smaller than the first term (C_{cOL}).

In a high beam current case (1.0<BC<30 nA) for electron beam inspections across care areas, Equation (5) can be simplified as Equation (12). Equation (12) shows the source image (d_{g}) and chromatic aberration blur are dominant in the electron beam column optics. Substituting Equation (1) and Equation (3) into Equation (12) finds an optimal numeric aperture angle (βₒₚₜ) given by Equation (13).

$$SS \approx {( {d}_{g}^{2} + {d}_{c}^{2} )}^{\frac{1}{2}} \qquad ( 12 )$$

$${β}_{opt}^{2} = {{k}_{2} ( \frac{BC * {V}_{LE}}{{B}_{r} * {( Cc * Δ E )}^{2}} )}^{1 / 2} \qquad ( 13 )$$

And the minimum spot size at βopt given by Equation (14) in which k₂ and p₂ are constants. In the high beam current regions for electron beam inspections, the total spot size (SS) increases slowly with the beam current and the image-formation resolution is limited by both the source energy spread ΔE and reduced brightness Bᵣ.

$$SS = {{ρ}_{2} ( \frac{{C}_{c}}{{V}_{LE}^{3 / 2}} )}^{1 / 2} * {( \frac{Δ E}{{B}_{r}^{1 / 2}} )}^{1 / 2} * {BC}^{1 / 4} \qquad ( 14 )$$

Equation (9) and Equation (14) may be referred to as resolution scaling laws for establishing optical architectures for metrologies and inspections. For the same electron beam optics column in FIG. 2, using different sources of electron emissions can provide different image-forming resolutions. For instance, a thermal field emission (TFE) emitter tip and a CFE emitter tip are used for comparisons, as can be characterized in the following table, which characterizes optical properties of a TFE source and a CFE source.

| | TFE | CFE |
|---|---|---|
| | source | source |
| Emitter tip radius (um) | 0.3 | 0.3 |
| Extractor voltage, Vₑₓₜ, (kV) | 3.2 | 6.4 |
| Virtual source angular intensity, Jₐ, (mA/sr) | 0.45 | 0.45 |
| Virtual source size, dᵥ, (nm) | 20 | 8 |
| Virtual source energy spread, ΔE, (eV, FWHM) | 1.25 | 0.45 |
| Virtual source reduced brightness, Bᵣ, (A/m\hat{ }2 · | 4.5E8 | 1.4E9 |
| sr · V) | | |
| Performance ratio Sqrt(ΔE/√Bᵣ) | 7.68E−3 | 3.47E−3 |

The numbers in the table are given based on experimental data and simulations with commercially available software. The performance ratio in the table shows that the CFE-based optical resolution may be more than 50% improved over a TFE-based optical resolution.

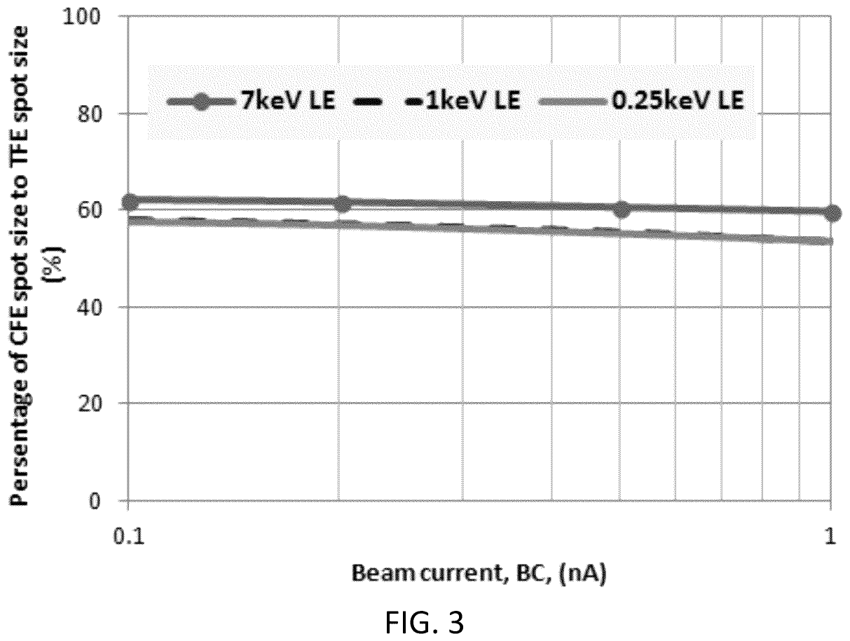

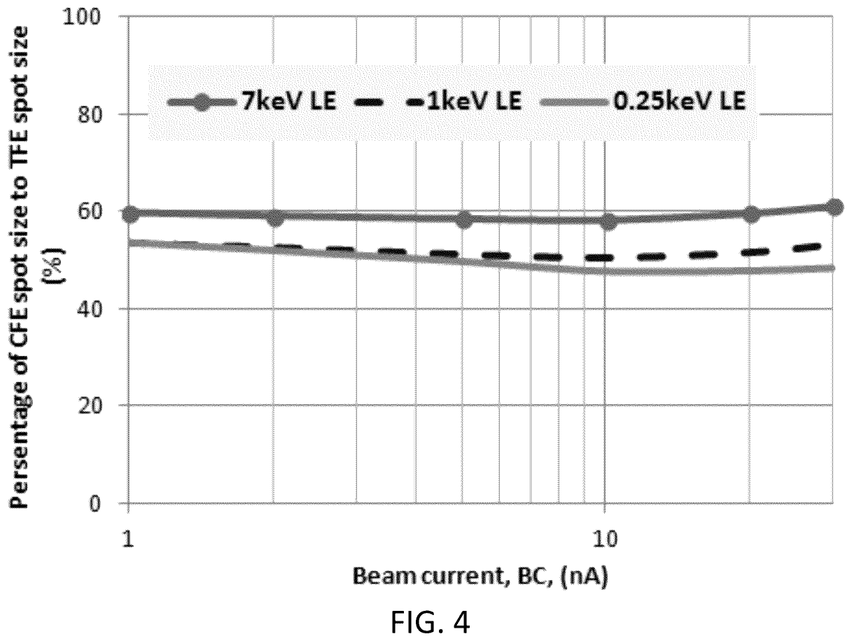

Complete SEM column optical simulations have been performed for testing the resolution scaling laws in Equation (9) and Equation (14), as shown in FIG. 3 and FIG. 4. From FIGS. 3 and 4, these scaling laws are useful across low landing energies (LE) to high landing energies. Limited differences between landing energies and beam currents are due to the differences of extractor voltages (Vₑₓₜ), which can cause the difference of optical magnification (M) in Equation (11) and difference of chromatic aberration coefficient (C_{c}) in Equation (10).

The scaling law Equation (14) for high beam current use cases shows benefits with CFE electron beam wafer inspections. At the same spot size (SS) with Equation (14), the beam current in a CFE-based electron optical column may be (7.68E−3/3.47E−3)\hat{ }4=24× higher than that in a TFE-based electron optical column (referring to the table). This ignores the slight change of C_{c} due to the extractor voltage difference. In other words, the electron beam scan speed may be 24× faster CFE over TFE optics at the same beam current density or the same ratio of signal to noise in image-formation. At the same beam current, the resolution with the CFE optics may be improved more than 50% over the TFE optics according to the performance ratio in the table.

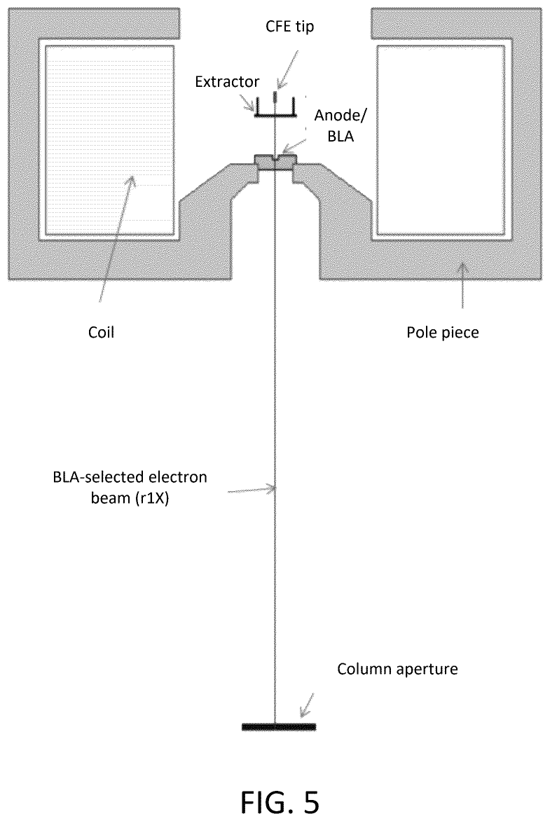

FIG. 5 is an embodiment of a CFE gun that meets the optical properties in the table. A large-radius CFE tip is deployed above an extractor electrode several millimeters. An anode electrode is deployed below the extractor around ten of millimeters. A beam limiting aperture (BLA) may be designed together with the anode. The anode and BLA may be grounded. The tip is biased at a negative voltage (e.g., from −5 kV to −50 kV) to provide sufficient beam energies in the electron beam optics. The extractor is biased at a potential higher from approximately 5 kV to 10 kV than the tip. The potential difference between the tip and extractor is referred to as the extractor voltage (e.g., the Vₑₓₜ in the table) for providing sufficiently high extracting field at the tip surface to emit electrons. The potential difference between the extractor and anode is referred to as acceleration voltage for accelerating the electrons to beam energies. Magnetic pole pieces are deployed around the tip-extractor-anode optics, and the excitation current through the magnetic coils is used to focus the electron beam and select the raw beam current after the BLA and final beam current after a column aperture.

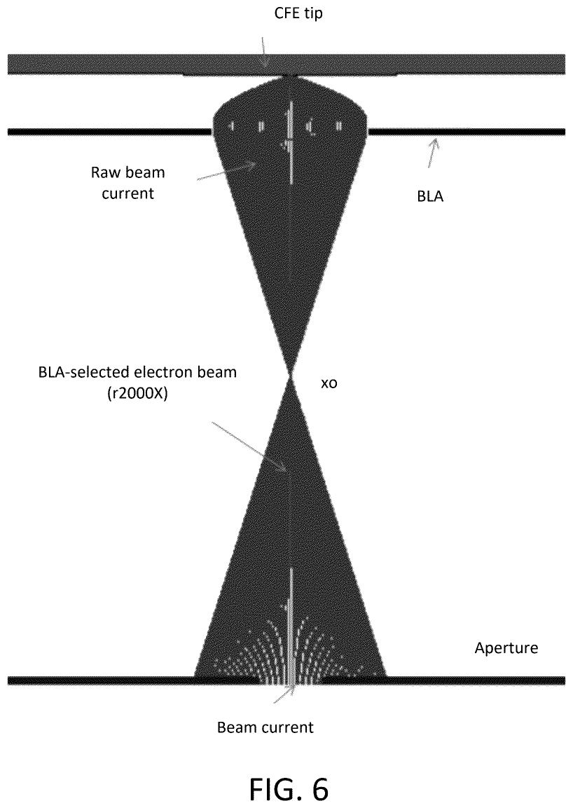

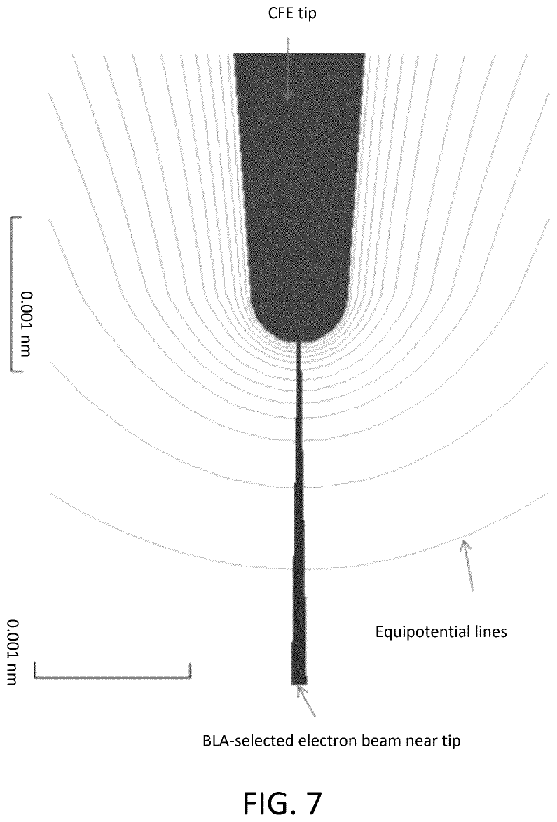

A simulation includes the mechanism of CFE electron emissions and trajectory of the electrons after emission from the CFE tip. FIG. 5 show the electron trajectories selected by the BLA in a radial scaling of r1X. FIG. 6 exhibits a r2000X-enlarged view of the trajectories of the emitting electrons from the CFE tip to column aperture. This shows that the BLA selects the raw beam current, and the column aperture selects the final beam current to the workpiece by changing the magnetic lens current (i.e., the beam crossover (xo) position). FIG. 7 exhibits the CFE emitting electrons (trajectories) near an emitter tip. The useful electrons are those selected by the beam limiting aperture. Based on FIG. 7, the emission area of the useful electrons is small, meaning that the virtual source size (dv) would be small (as shown in the table) or that the brightness would be high (Equation (6)). The virtual source position is near the center of the circle with the tip radius. The virtual source size (dv) is the size of the crossover formed by the back-extended trajectories in FIG. 7.

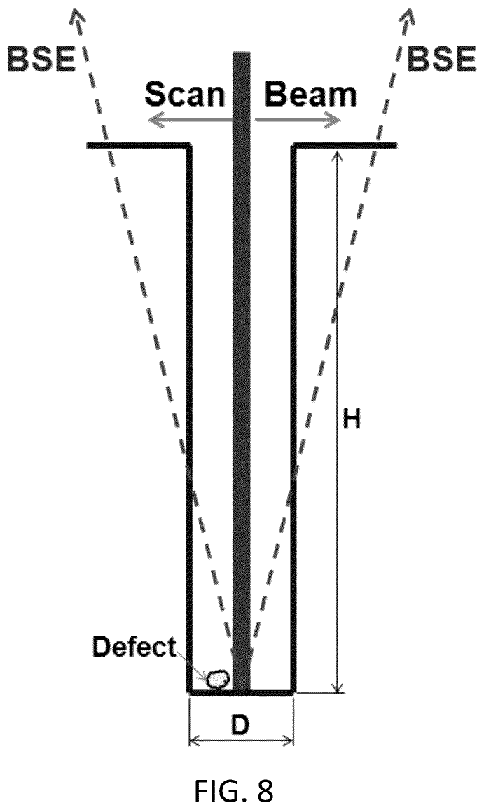

For some applications, it may not be possible to define the care area by the BBP optical inspection because an optical inspector can only detect the defects on the surface of a workpiece. For example, a 3D NAND device consists of hundreds of millions of memory holes (or contact holes), as shown in FIG. 8. The ratio of the width (D) to depth (H) of a memory hole may be, for example, 1:100 (e.g., H=5.0 microns if D=0.05 microns). The high aspect ratio (HAR) memory holes are normally etched, so the defects may be formed at the bottom of a hole (FIG. 8). Optical inspection methods including the BBP optical inspections can only be possible to detect the surface defects, which can fail to define the care areas of defects at HAR bottoms.

Without using BBP inspections in FIG. 2, the care areas can be defined based on a design file corresponding to the areas of interest. A design file generally refers to the physical design (layout) of an IC and data derived from the physical design through simulations. These design files may be read by the processor 110 in FIG. 2, and users may define some or all the care areas with the computations and communications with the electron beam optical column. An improved defect location accuracy (DLA) system can be used for better locating the care areas defined with a design file in the electron beam optics column.

To detect the defects at the bottom of an HAR hole, the electron beam can be scanned within the hole, as shown in FIG. 8. This requires a large depth of focus (DOF) electron beam. The secondary electrons may be unable to escape the hole from the bottom because they are stopped by the wall of the HAR hole. Low emission energies and large emission polar angles prevent secondary electrons from escaping the hole. Accordingly, a high landing energy (LE) electron beam with large DOF is used to scan the bottom of the HAR holes. The back-scattered electrons (BSEs) with high emission energies may penetrate through the materials around the wall of the HAR hole and escape from the top surface of the memory holes, as shown in FIG. 8. These BSEs may be collected by the annular detector 109 in FIG. 2.

The SEM optics column with a high brightness CFE source shown in FIG. 2 and FIG. 5 may be operational at high beam energies (e.g., BE=50 keV) and high landing energies (e.g., LE=45 keV) with an adjustable working distance to focus the high LE beam onto the workpiece without the objective lens (OL) magnetic saturation. The working distance is the distance between the objective lens and workpiece. The optical magnification of the optics may be as large as possible to focus the beam with a small numeric aperture (NA) because the virtual source size is small in a CFE-based optics, as shown in the table. The NA may be, for example, from approximately 1.5 to 5.0 mrad.

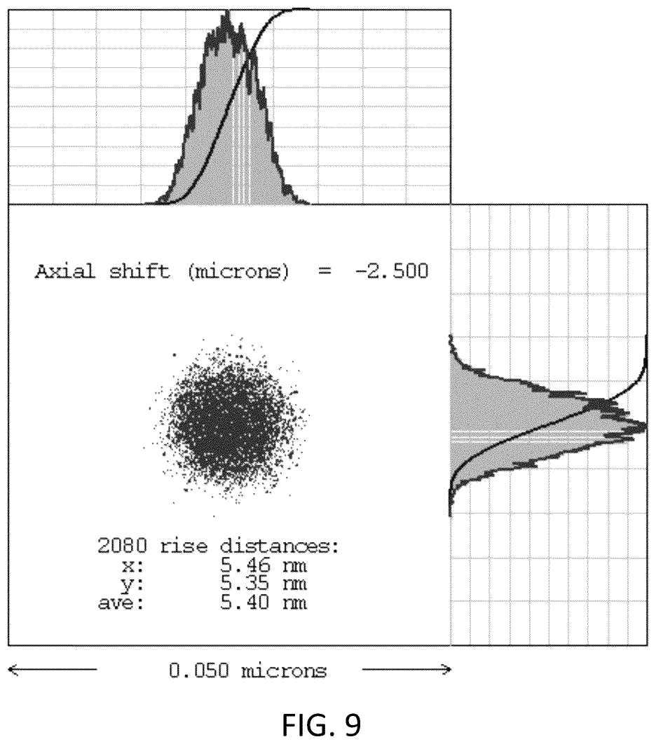

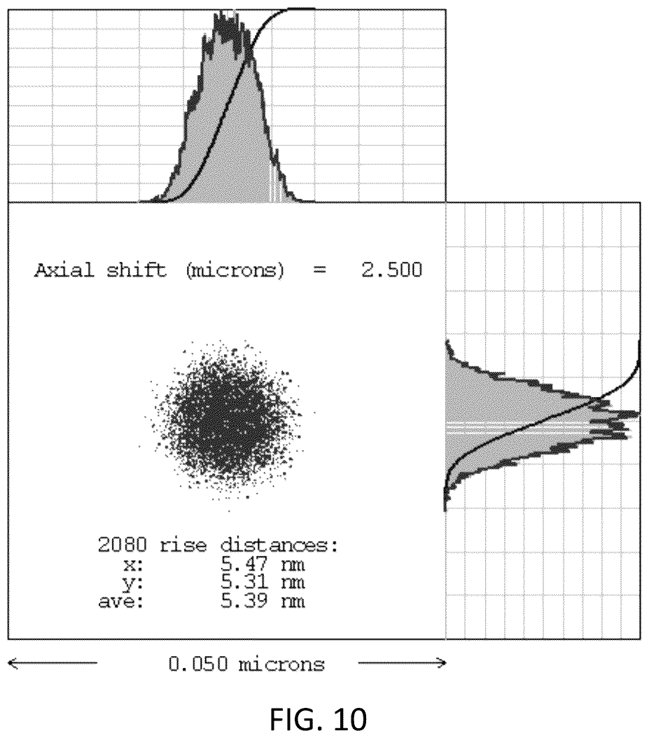

Computer simulations shown in FIGS. 9-10 demonstrate beam spot sizes. The beam current (BC) is 10 nA in the simulation and includes Coulomb interactions between electrons. Other conditions with the simulation include a beam energy of 50 keV, a landing energy of 45 keV, and a numeric aperture of 2 mrad. FIGS. 9-10 show the spot sizes at the top surface (2=−2.5 μm) and bottom surface (2=2.5 μm) of a memory hole with a depth of 5 μm, respectively. For a 1:100 HAR, the electron beam can still scan within the memory hole because the spot size is only 5.4 nm but the width of the hole may be 50 nm.

Embodiments disclosed herein can provide an optical column with a wide range of selective conditions (e.g., landing energy from approximately 0.1 to 50 keV and/or resolution down to one nanometer). This can include a high brightness cold field emission electron source with a reduced brightness value Br≥1.4×10⁹ A/(m²·sr·V). The cold field emission electron source emitter tip may have a large radius and a high extractor voltage for extracting electron emissions with high brightness. The electron emission may have low source energy spreads with high extractor voltages due to reducing Boersch effect, which is an energy spread effect induced by Coulomb interactions between electrons. The magnetic lens may have low aberrations because the working distance (the distance between the tip and the principal plane of the magnetic lens) is reduced. A Wien filter and side detector subsystem can collect secondary electrons in detecting 2D defects with lower primary electron landing energies. The defects on the surface of workpiece are referred to as 2D defects. An annular detector subsystem can collect back scattered electrons in detecting 3D defects with higher primary electron landing energies. The defects in the deep layers of substrates (e.g., at the bottom of a 3D NAND memory hole) are referred to as 3D defects. A high-resolution electron beam scanning system can include one or two deflectors due to reduced transverse chromatic aberrations with low source energy spreads.

The system can be integrated with one or more optical inspectors and/or an IC layout design generator. The one or more optical inspectors can define the care areas of defects detected on the surface or underneath the surface of the workpiece. The processor can define the care areas of defects possibly buried in deep layers of the workpiece. The processor may generate or communicate with other databases for IC layout data files. The defect location accuracy (DLA) system can coordinate the electron beam system with the optical inspector.

Using Equation (14), the sensitivities (resolutions) of 2D defect detections can be projected. The electron beam spot size may be directly proportional to SS˜[ΔE/√Bᵣ]^{1/2}, thereby resulting in the electron optical design with a high brightness cold field emission gun. As a result, the electron beam image-forming resolution may be reduced to one nanometer. Equation (1) can be used to project the sensitivities (resolutions) of 3D defect detections. In a high landing energy optics (e.g., LE>30 keV), the source image (d_{g} in Equation (1)) may be dominant over the spherical aberration blur (dₛ in Equation (2)), the chromatic aberration blur (d_{c} in Equation (3)), and the diffraction aberration blur (d_{λ} in Equation (4)). Thus, in the 3D defect detections with high landing energies, the electron beam spot size may be directly proportional to SS˜1/√Bᵣ, thereby resulting in the electron optical design with a high brightness cold field emitter gun. As a result, a 3D NAND memory hole of 1:100 high aspect ratio may be scanned by a high DOF (e.g., 5 microns) electron beam. Concepts of care area workpiece inspection improve the efficiency of defect detection algorithms by reducing the amount of image processing needed and increasing the probability of filtering important defects of interests.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a cold field emission electron source that generates an electron beam;
a stage configured to hold a workpiece in a path of the electron beam;
a magnetic lens disposed along the path of the electron beam between the cold field emission source and the stage;
a Wien filter disposed along the path of the electron beam between the magnetic lens and the stage;
a detector configured to collect secondary electrons;
an annular detector configured to collect back scattered electrons; and
a scanning system disposed along the path of the electron beam between the magnetic lens and the Wien filter, wherein the scanning system includes at least one deflector.

2. The system of claim 1, wherein the cold field emission source has an emitter tip with a radius configured to provide an electron emission of at least 1.4×10⁹ A/(m²·sr·V).

3. The system of claim 1, further comprising a processor in electronic communication with the system and an optical inspector in electronic communication with the processor.

4. The system of claim 3, wherein the processor is configured to:
define at least one care area on the workpiece for defects detected on a surface or underneath a surface of the workpiece using data from the optical inspector; and
define at least one care area for the workpiece that includes defects buried in the workpiece.

5. The system of claim 4, wherein the at least one care area on the surface of the workpiece is based on the data from the optical inspector.

6. The system of claim 4, further comprising a defect location accuracy system operated by the processor, wherein the defect location accuracy system is configured to determine how accurately the coordinate systems of the system and the optical inspector are matched.

7. A method comprising:
generating an electron beam with a cold field emission electron source;
directing the electron beam through a magnetic lens;
directing the electron beam through a scanning system downstream of the magnetic lens;
directing the electron beam through a Wien filter downstream of the scanning system;
directing the electron beam to a workpiece on a stage;
detecting secondary electrons from the workpiece with a side detector; and
detecting back scattered electrons with an annular detector.

8. The method of claim 7, wherein the cold field emission source has an emitter tip with a radius and voltage configured to provide an electron emission of at least 1.4×10⁹ A/(m²·sr·V).

9. The method of claim 8, wherein the electron emission has a source energy spread from 0.4 to 0.5 eV, and wherein a Boersch effect is reduced to less than 0.5 eV.

10. The method of claim 7, wherein the magnetic lens has a working distance between an objective lens and the workpiece of 1 to 3 mm.

11. The method of claim 7, wherein the side detector is configured to provide data for detecting defects on a surface of the workpiece.

12. The method of claim 7, wherein the annular detector is configured to provide data for detecting defects buried in the workpiece.

13. The method of claim 7, wherein the scanning system provides an energy spread from 0.4 to 0.5 eV thereby reducing transverse chromatic aberrations.

14. The method of claim 7, further comprising defining at least one care area on the workpiece for defects detected on a surface or underneath a surface of the workpiece using a processor, wherein the at least one care area on the workpiece for defects detected on a surface or underneath a surface of the workpiece are defined using data from an optical inspector.

15. The method of claim 14, further comprising defining at least one care area for the workpiece that includes defects buried in the workpiece using the processor.

16. The method of claim 7, wherein resolution of the electron beam is 1 nm or less.

17. The method of claim 7, wherein a high aspect ratio structure on the workpiece is inspected using the electron beam.
